(19) United States
(12) Patent Application Publication
(10) Pub. No.: US 2026/0133764 A1
(43) Pub. Date: May 14, 2026

(54) SEMICONDUCTOR DEVICE AND COMMUNICATION SYSTEM

(71) Applicant: ROHM CO., LTD., Kyoto (JP)

(72) Inventor: Kei Nagao, Kyoto (JP)

(21) Appl. No.: 19/436,167

(22) Filed: Dec. 30, 2025

Related U.S. Application Data
(63) Continuation of application No. PCT/JP2024/020847, filed on Jun. 7, 2024.

(30) Foreign Application Priority Data
Jul. 6, 2023 (JP) 2023-111348

(51) Int. Cl. G06F 7/62; H03K 7/08

(52) U.S. Cl. CPC G06F 7/62; H03K 7/08

(57) ABSTRACT

Write data transmitted by serial communication includes sign data indicating decrementing or incrementing, gain data indicating a gain value, and relative value data indicating a relative change value. A relative calculator calculates a calculation result by decrementing or incrementing, according to the sign data, the current value of the duty setting data by the value obtained by multiplying the relative change value by the gain value. An updating controller updates the duty setting data according to the calculation result.

### CROSS-REFERENCE TO RELATED APPLICATIONS

This nonprovisional application is a continuation application of International Patent Application No. PCT/JP2024/020847 filed on Jun. 7, 2024, which claims priority to Japanese Patent Application No. 2023-111348 filed on Jul. 6, 2023, the entire contents of which are hereby incorporated by reference.

### TECHNICAL FIELD

The present disclosure relates to semiconductor devices and communication systems.

### BACKGROUND ART

Semiconductor devices provided with a serial communication function are used in a variety of applications.

One example of a circuit technology related to serial communication is seen in Patent Document 1 identified below.

### CITATION LIST

### Patent Literature

Patent Document 1: Japanese Unexamined Patent Application No. 2017-224946

### BRIEF DESCRIPTION OF DRAWINGS

FIG. 1 is a diagram showing the configuration of a communication system according to an illustrative embodiment of the present disclosure.

FIG. 2 is a diagram showing the configuration of a semiconductor device according to an illustrative embodiment of the present disclosure.

FIG. 3 is a diagram showing the data structure of reception data RX.

FIG. 4 is a diagram showing a configuration example related to the updating of dimming settings in a semiconductor device.

FIG. 5 is a diagram showing a register map in a high resolution mode.

FIG. 6 is a diagram showing the correspondence between the addresses transmitted in reception data RX and the data corresponding to those addresses.

FIG. 7 is a configuration diagram showing an example of updating dimming setting data in the high resolution mode and in addition in a relative mode.

FIG. 8A is a diagram showing an example of data transmitted in reception data RX in the high resolution mode an in addition in an absolute mode.

FIG. 8B is a diagram showing an example of data transmitted in reception data RX in the high resolution mode and in addition in the absolute mode.

FIG. 8C is a diagram showing an example of data transmitted in reception data RX in the high resolution mode and in addition in the absolute mode.

FIG. 9 is a configuration diagram showing an example of updating dimming setting data in the high resolution mode and in addition in the absolute mode.

FIG. 10 is a diagram showing one example of the correspondence between the range of the on-duty in gradation dimming and the steps in which the on-duty is changed.

FIG. 11 is a diagram showing a register map in a low resolution mode.

FIG. 12 is a configuration diagram showing an example of updating dimming setting data in the low resolution mode an in addition in the absolute mode.

FIG. 13 is a diagram showing a register map related to a group setting function.

FIG. 14 is a configuration diagram showing an example of updating dimming setting data using the group setting function.

### DESCRIPTION OF EMBODIMENTS

Illustrative embodiments of the present disclosure will be described below with reference to the accompanying drawings.

### <1. Communication System>

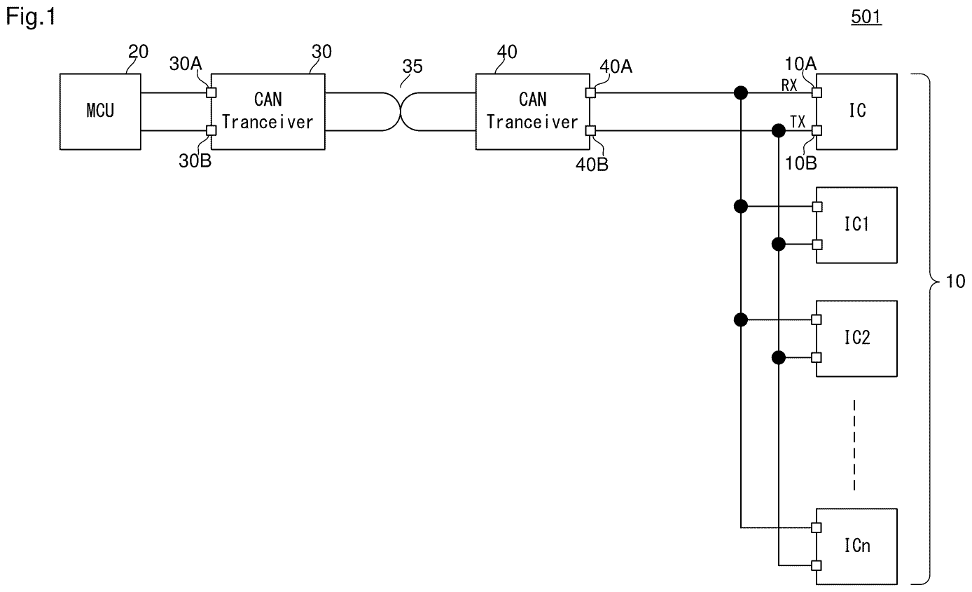

FIG. 1 is a diagram showing the configuration of a communication system 501 according to an illustrative embodiment of the present disclosure. The communication system 501 includes an MCU (microcontroller unit) 20, a CAN (controller area network) transceiver 30, a CAN transceiver 40, and a plurality of semiconductor devices 10. The communication system 501 is, for example, for use on-board a vehicle.

Between the MCU 20 and the CAN transceiver 30, communication is performed by UART (universal asynchronous receiver/transmitter). UART is a protocol for exchange of serial data between two devices. In UART, bidirectional communication is performed across two lines between the transmission side and the reception side.

Between the can transceivers 30 and 40, communication is performed across a CAN bus 35. CAN is a serial communication protocol standardized in international standards such as ISO11898.

The CAN transceiver 30 has a TXD (transmission data input) terminal 30A and an RXD (reception data output) terminal 30B. By the CAN transceiver 30, data input to the TXD terminal 30A is output to the CAN bus 35 and data input from the CAN bus 35 is output from the RXD terminal 30B.

The CAN transceiver 40 has an RXD terminal 40A and a TXD terminal 40B. By the CAN transceiver 40, data input to the TXD terminal 40B is output to the CAN bus 35 and data input from the CAN bus 35 is output from the RXD terminal 40A.

The semiconductor device 10 is an IC (integrated circuit) that has integrated in it a circuit with a predetermined function, and is configured as, for example, an LED (light-emitting diode) driver IC. The plurality of semiconductor devices 10 can all be LED driver ICs or only one or some of them can be LED driver ICs. The semiconductor device 10 as an LED driver IC will be described in detail later.

The semiconductor device 10 has an RX (reception data input) terminal 10A and a TX (transmission data output) terminal 10B. The RX terminals 10A of all the plurality of semiconductor devices 10s are connected to the RXD terminal 40A. The TX terminals 10B of all the plurality of semiconductor devices 10s are connected to the TXD terminal 40B.

Reception data RX output from the RXD terminal 40A is input to the RX terminal 10A of each of the plurality of semiconductor devices 10. The reception data RX has specified in it the device address of one of the plurality of semiconductor devices 10. Transmission data TX output from the TX terminal 10B of each of the plurality of semiconductor devices 10 is input to the TXD terminal 40B.

### <2. Configuration of the Semiconductor Device>

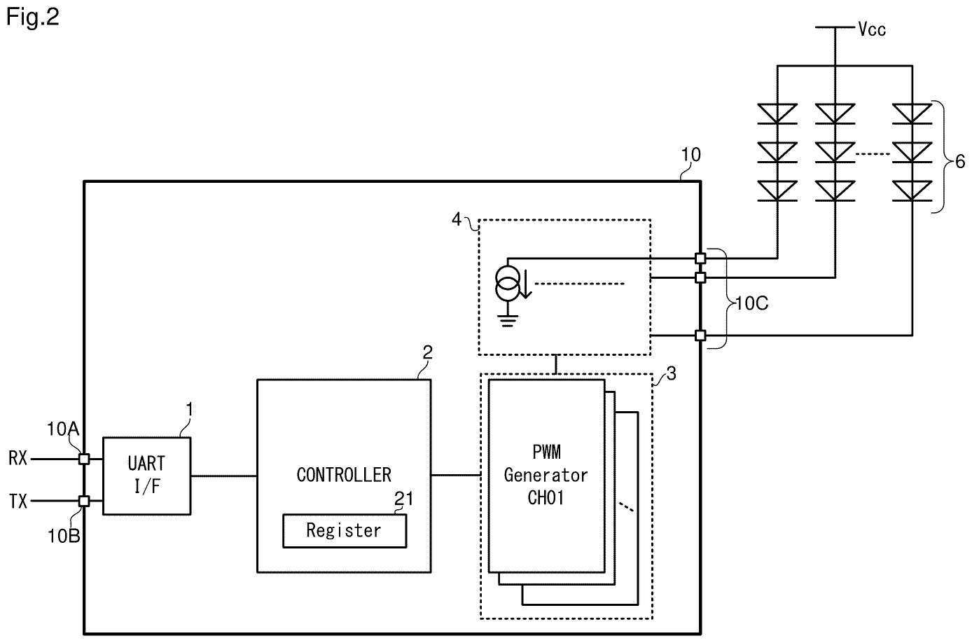

FIG. 2 is a diagram showing the configuration of a semiconductor device 10 according to an illustrative embodiment of the present disclosure. The semiconductor device 10 shown in FIG. 2 is configured as an LED driver IC for driving an LED 6. An LED is one example of a light-emitting element. That is, an LED driver is one example of a light-emitting element driving device.

The LED 6 comprises LEDs provided in a plurality of channels. The following description assumes, as one example, that there are provided 24 channels. There can be provided any number other than 24 of channels of LEDs or a single channel of LEDs. Each channel is configured with LEDs 6 connected in series. Each channel can be configured with LEDs 6 connected in series and in parallel, or with a single LED.

The semiconductor device 10 has integrated in it a UART interface 1, a controller 2, a PWM generator 3, and a current driver 4. The semiconductor device 10 also has, as external terminal for communication with the outside, an RX terminal 10A, a TX terminal 10B, and a cathode terminal 10C.

As mentioned above, reception data RX input from the outside to the RX terminal 10A is input to the UART interface 1. On the other hand, transmission data TX output from the UART interface 1 is, as mentioned above, output from the TX terminal 10B to the outside.

The controller 2 has a register 21. If the reception data RX input to the UART interface 1 indicates a write (writing-in), based on write data included in the reception data RX, the controller 2 updates data in the register 21. On the other hand, if the reception data RX input to the UART interface 1 indicates a read (reading-out), the controller 2 reads data from the register 21. The RX data will be described in detail later.

There are provided as many PWM generators 3 as the number of channels of LEDs 6. Accordingly, if 24 channels of LEDs 6 are provided, the PWM generators 3 are provided one for each of channels CH01 to CH24. “Channel CHn” corresponds to the nth channel. The register 21 stores dimming setting data for each channel. The PWM generator 3 for each channel generates a PWM signal with an on-duty based on the dimming setting data for that channel. That is, the dimming setting data for each channel represents the on-duty for PWM dimming for that channel.

A PWM signal is a pulse signal that is either at high level or at low level at a time. Within one cycle (PWM period), the period in which a PWM signal is at a first level (e.g., high level) is the on period and the period in which a PWM signal is at a second level (e.g., low level) is the off period.

There are provided as many current drivers 4 as the number of channels of LEDs 6. Accordingly, if 24 channels of LEDs 6 are provided, the current drivers 4 are provided one for each of channels CH01 to CH24. The current driver 4 of each channel is connected via the corresponding cathode terminal 10C to the cathode of the LED 6 of that channel. The anode of the LED 6 of each channel is all connected to an application terminal for a supply voltage Vcc.

The PWM signal generated by the PWM generator 3 for each channel is used for on/off control of the current driver 4 for that channel. Specifically, in the on period of the PWM signal, the current driver 4 is kept in on state and, in the off period of the PWM signal, the current driver 4 is kept in off state. With the current driver 4 in on state, a constant current passes through the LED 6, which is thus lit; with the current driver 4 in off state, no constant current passes through the LED 6, which thus remains extinguished. The on-duty of PWM dimming is the proportion of the on period within one cycle. The higher the on-duty, the brighter the LED 6 is lit.

With the above configuration, based on reception data RX over UART communication, the dimming setting data for each channel is updated and, based on the on-duty set for each channel, PWM dimming can be performed for the LED 6 of that channel. As will be discussed later, in the embodiment, with a single session of communication of reception data RX, the dimming setting data for all the 24 channels can be updated or the dimming setting data for only one or some channels (a single channel or a plurality of channels) can be updated.

### <3. Structure of Reception Data>

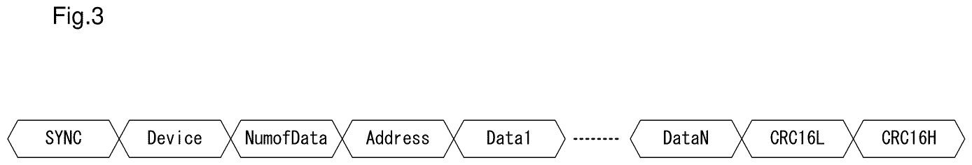

FIG. 3 is a diagram showing the data structure of reception data RX. In UART, communication is performed in data units called frames. A frame is composed of bit data starting with a start bit and ending with a stop bit. The start bit is low level and the stop bit is high level. Between the start bit and the stop bit is arranged bit data composed of a predetermined number of bits. The following description assumes, as one example, that the predetermined number of bits are eight. In that case, a frame is composed of bit data of 10 bits.

As shown in FIG. 3, the reception data RX has, in order from its beginning, a synchronization frame SYNC, a device frame Device, a number-of-data frame NumofData, an address frame Address, data frames Data1 to DataN (where N is an integer of one or more), a CRC (cyclic redundancy check) lower frame CRC19L, and a CRC higher frame CRC16H.

The synchronization frame SYNC is bit data for setting the baud rate in the semiconductor device 10.

The device frame Device includes a device address, a Read/Write bit, and the like. The device address is bit data that indicates the address of a target device (semiconductor device 10). The Read/Write bit is bit data that indicates a read or a write.

The number-of-data frame NumofData is bit data that indicates the number of frames (i.e., N) in the data frames Data1 to DataN.

The address frame Address is bit data that indicates the address for access to the register 21.

The data frames Data1 to DataN are bit data that indicates the data for updating the data in the register 21. If, in the device frame Device, the Read/Write bit indicates a read, no data frames Data1 to DataN are included in the reception data RX.

The CRC lower frame CRC19L and the CRC higher frame CRC16H are bit data that indicates error detection codes added to the data frames Data1 to DataN.

### <4. Updating the Dimming Settings>

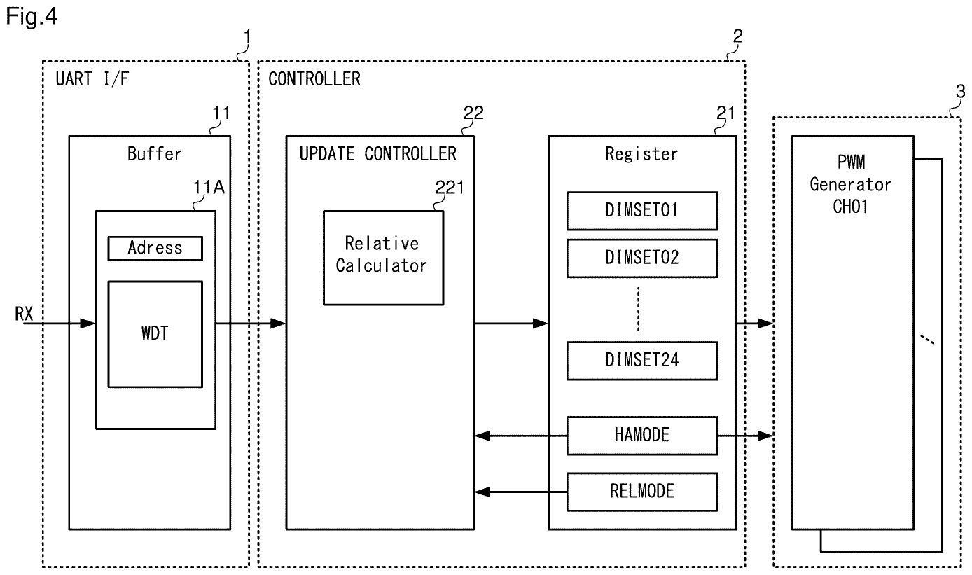

Next, how the dimming setting data in the register 21 is updated will be described. FIG. 4 is a diagram showing a configuration example related to the updating of dimming settings in the semiconductor device 10.

As shown in FIG. 4, the UART interface 1 has a buffer 11. When the reception data RX is input to the buffer 11, the reception data 11A is stored in the buffer 11. The reception data 11A includes address data Address and write data WDT. The write data WDT is data that is transmitted in the data frame DataN (FIG. 3).

The controller 2 has, along with the register 21, an update controller 22. Based on the reception data 11A, the update controller 22 updates the dimming setting data DIMSET01 to DIMSET24 in the register 21. The update controller 22 includes a relative calculator 221. The relative calculator 221 is used in relative updating of dimming setting data, which will be described later.

The register 21 stores dimming setting data DIMSET01 to DIMSET24. The dimming setting data DIMSETn is a dimming setting for channel CHn and indicates the on-duty for channel CHn. An on-duty has a value from 0% to 100%.

The register 21 also stores resolution setting data HAMODE and relative mode setting data RELMODE.

The resolution setting data HAMODE is one-bit data and indicates which of a high resolution mode and a low resolution mode is set. The high resolution mode is a mode in which the dimming setting data DIMSETn is updated as having a first number of bits (e.g., 12 bits) and in which the on-duty can be adjusted at a resolution of the first number of bits. For example, if the first predetermined number of bits is 12, the on-duty can be adjusted in steps of about 0.02%. The low resolution mode is a mode in which the dimming setting data DIMSETn is updated as having a second predetermined number of bits (e.g., eight bits) smaller than the first predetermined number of bits and in which the on-duty can be adjusted at a resolution of the second number of bits. For example, if the second predetermined number of bits is eight, the on-duty can be adjusted in steps of about 0.4%.

The relative mode setting data RELMODE is one-bit data and indicates which of a relative mode and an absolute mode is set. The relative mode is a mode in which the dimming setting data DIMSETn is updated by being changed relatively from its current value. The absolute mode is a mode in which the dimming setting data DIMSETn is updated with an absolute value.

### <<High Resolution Mode>>

A description will now been given of how dimming setting data is updated when the resolution mode is set to the high resolution mode (HAMODE=1). Here, as one example, it is assumed that the first predetermined number of bits mentioned above is 12.

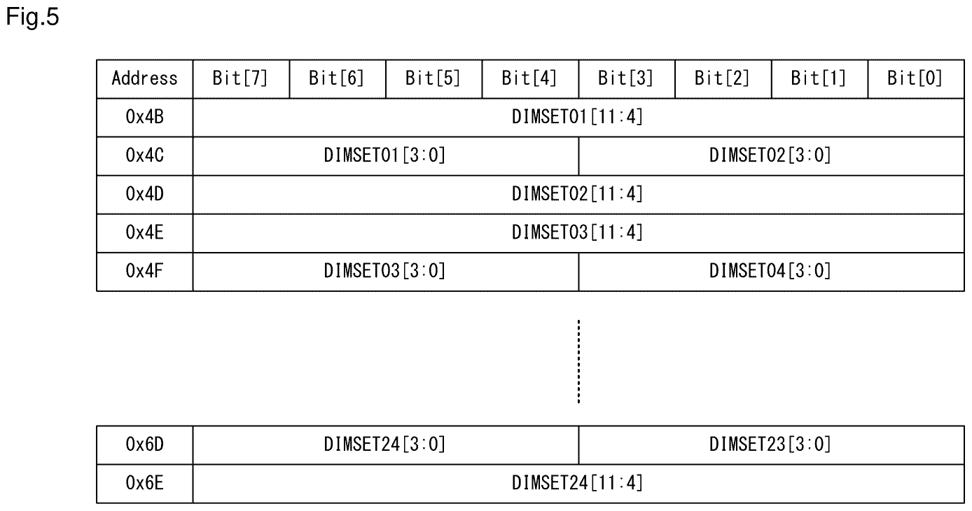

FIG. 5 is a diagram showing how dimming setting data DIMSETn is stored in the register 21 in the high-resolution mode. Specifically, FIG. 5 is a register map. FIG. 5 shows the correspondence between the addresses in the register 21 and the dimming setting data DIMSETn stored at those addresses. As shown in FIG. 5, eight-bit data can be stored per address. The number of bits that can be stored at one address in the register 21 is the second predetermined number of bits (the number of bits at low resolution) mentioned above.

The values of the addresses shown in FIG. 5 and the following figures are merely one example. At address 0x4B, the upper eight bits of DIMSET01 are stored. At address 0x4C, the lower four bits of DIMSET01 are stored in the upper bits and the lower four bits of DIMSET02 are stored in the lower bits. At address 0x4D, the upper eight bits of DIMSET02 are stored. In patterns similar to that of the dimming setting data stored at address 0x4B to 0x4D, DIMSET03 to DIMSET24 are stored at addresses starting at 0x4E. In this way, at the consecutive addresses from 0x4B to 0x6E, DIMSET01 to DIMSET24, each composed of 12 bits, can be stored.

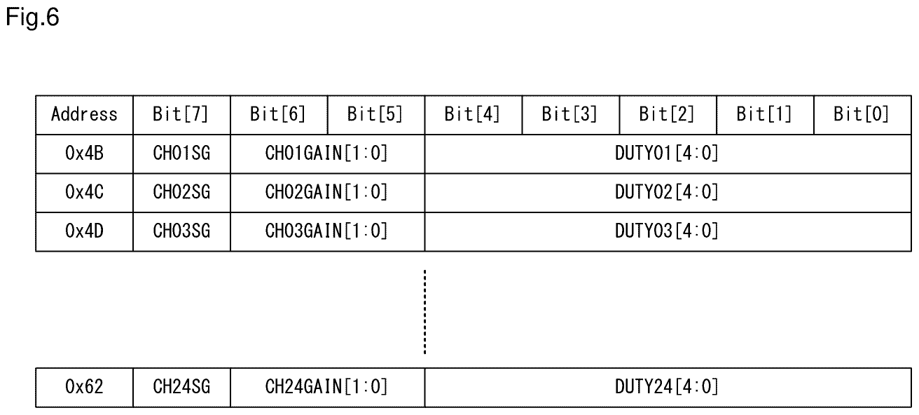

A description will now be given of a case where the high resolution mode is set and in addition the relative mode (RELMODE=1) is set. FIG. 6 is a diagram showing the correspondence, in that case, between the addresses transmitted in the reception data RX and the data corresponding to those addresses. The addresses shown in FIG. 6 are transmitted in the address frame Address (FIG. 3). The eight-bit data (Bit[7:0]) shown in FIG. 6 is transmitted in the data frame DataN (FIG. 3).

The eight-bit data includes sign data CHnSG, gain data CHnGAIN, and relative value data DUTYn. The sign data CHnSG. the gain data CHnGAIN, and the relative value data DUTYn are data corresponding to channel CHn.

The sign data CHnSG is one-bit data and indicates a decrement or increment from the current value of the dimming setting data DIMSETn. For example, GHnSG=0 indicates a decrement and GHnSG=1 indicates an increment.

The gain data CHnGAIN is two-bit data and indicates a gain value. For example, CHnGAIN=0 indicates a one-time (unity) gain, CHnGAIN=1 indicates a twice gain, CHnGAIN=2 indicates an eight-time gain, and CHnGAIN=3 indicates a 16-time gain.

The relative value data DUTYn is five-bit data and indicates a relative change value. The relative value data DUTYn can take a value from zero to 31.

With the sign data CHnSG, the gain data CHnGAIN, and the relative value data DUTYn, the dimming setting data DIMSETn for channel CHn is updated in the following manner.

$$DIMSETn = DIMSETn \pm DUTYn \times CHnGAIN$$

Here, DIMSETn in the right side represents the current value and DIMSETn in the left side represents the updated value. The sign “±” indicates either “+” (increment) or “−” (decrement) according to the sign data CHnSG.

For example, if CHnSG=0, CHnGAIN=1, and DUTYn=5, then DIMSETn=DIMSETn−5×2.

The eight-bit data corresponding to the addresses shown in FIG. 6 is the data that is transmitted in the beginning data frame Data1 when those addresses are transmitted in the address frame Address. While it is possible to transmit the part of the beginning data frame Data1 corresponding to one channel, when the part of it corresponding to a plurality of channels are transmitted, the data starting with the beginning data frame Data1 corresponding to consecutive channels is transmitted in a plurality of data frames. For example, when data corresponding to 24 channels is transmitted, with the address transmitted in the address frame Address set to 0x4B, data corresponding to 24 channels (CH01SG to CH24SG, CH01GAIN to CH24GAIN, and DUTY01 to DUTY24) is transmitted in 24 data frames.

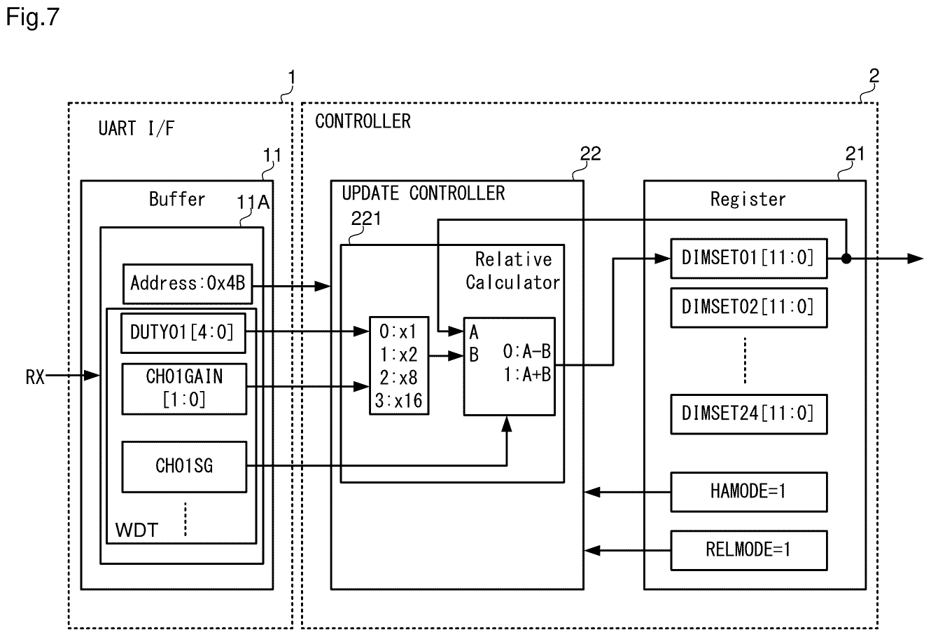

FIG. 7 is a configuration diagram showing an example of updating dimming setting data DIMSETn in a case where the high resolution mode is set and in addition the relative mode is set (HAMODE=1, RELMODE=1; corresponding to FIG. 4). FIG. 7 shows an example in which the address 0x4B is transmitted in the address frame Address.

Reception data RX is input to the UART interface 1 and reception data 11A is stored in the buffer 11. The reception data 11A includes, along with the address 0x4B, write data WDT. The write data WDT includes the sign data CH01SG, the gain data CH01GAIN, and the relative value data DUTY01 corresponding to channel CH01. In this case, in the relative calculator 221, the following calculation is performed.

$$DIMSET 01 = DIMSET 01 \pm DUTY 01 \times CH 01 GAIN .$$

With the value of the dimming setting data DIMSET01 for channel CH01 calculated as described above, the value of the dimming setting data DIMSET01 in the register 21 is updated.

Though omitted from illustration in FIG. 7, the updating of the dimming setting data DIMSETn for channel CH02 and the following channels is performed in a similar manner as described above.

Next, a description will be given of how dimming setting data is updated in a case where the high resolution mode is set and in addition the absolute mode is set (HAMODE=1, RELMODE=0).

In this case, with the reception data RX, transmission is performed in the following manner. In the register map (FIG. 5) of the register 21, the address corresponding to the beginning channel for which the dimming setting data needs to be updated is specified in the address frame Address. Moreover, the dimming setting data DIMSETn corresponding to consecutive addresses starting with the address specified in the above register map corresponding to as many channels as needed is transmitted in the data frame DataN.

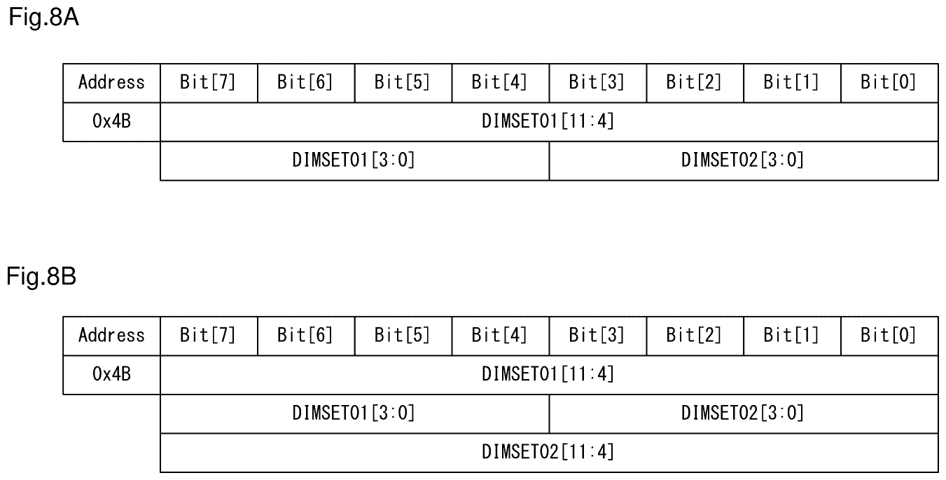

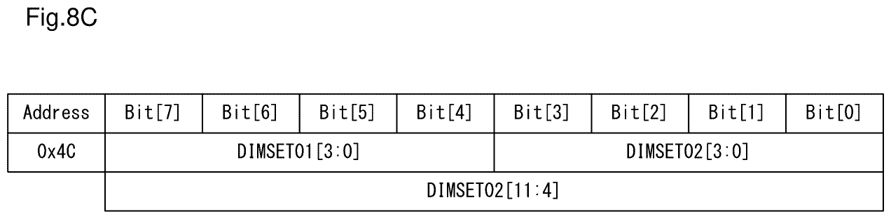

For example, FIG. 8A shows the data transmitted in the reception data RX when the sole channel for which updating is needed is channel CH01. In this case, 0x4B is specified in the address frame Address, the upper bits of DIMSET01 are transmitted in the data frame Data1, and the lower bits of DIMSET01 are transmitted in the data frame Data2. In this case, the lower bits of DIMSET02 for channel CH02 hold dummy data.

For another example, FIG. 8B shows the data transmitted in the reception data RX when the channels for which updating is needed are channels CH01 and CH02. In this case, 0x4B is specified in the address frame Address, the upper bits of DIMSET01 are transmitted in the data frame Data1, the lower bits of DIMSET01 and the lower bits of DIMSET02 are transmitted in the data frame Data2, and the upper bits of DIMSET 02 are transmitted in the data frame Data3.

For yet another example, FIG. 8C shows the data transmitted in the reception data RX when the sole channel for which updating is needed is channel CH02. In this case, 0x4C is specified in the address frame Address, the lower bits of DIMSET02 are transmitted in the data frame Data1, and the upper bits of DIMSET02 are transmitted in the data frame Data2. In this case, the lower bits of DIMSET01 for channel CH01 hold dummy data.

With the dimming setting data DIMSETn transmitted as described above, the dimming setting data DIMSETn in the register 21 is updated. However, the data in the register 21 is not updated with the dummy data.

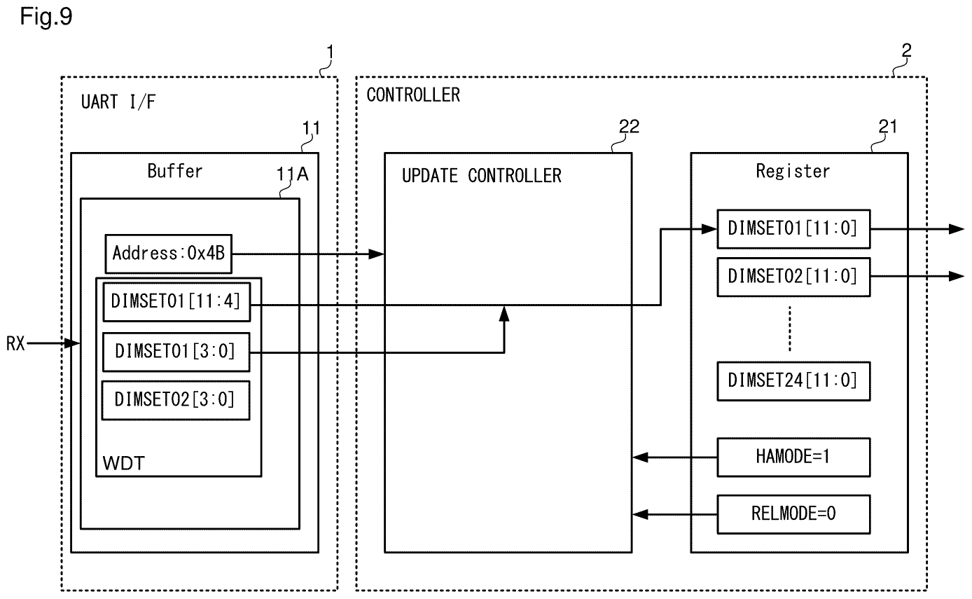

FIG. 9 is a configuration diagram (corresponding to FIG. 4) showing an example of updating the dimming setting data DIMSETn when the high resolution mode is set and in addition the absolute mode is set (HAMODE=1, RELMODE=0; corresponding to FIG. 4). FIG. 9 shows an example where only the dimming setting data DIMSET01 for channel CH01 is updated.

Reception data RX is input to the UART interface 1 and reception data 11A is stored in a buffer 11. The reception data 11A includes, along with the address 0x4B, write data WDT. In the write data WDT, the upper and lower bits of DIMSET01 and the lower bits of DIMSET02 are stored (FIG. 8A). Thus, based on the address 0x4B and the upper and lower bits of DIMSET01, the update controller 22 updates the DIMSET01 in the register 21.

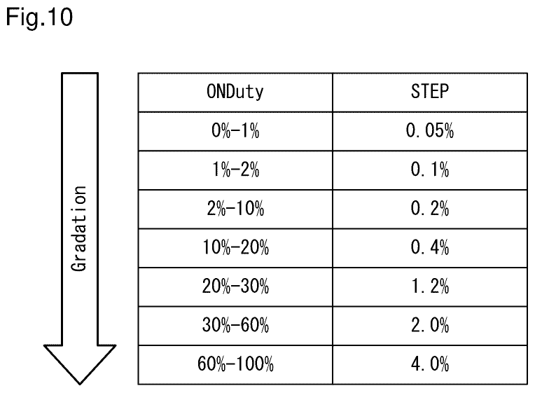

As described above, with the embodiment, it is possible to update high-resolution (e.g., 12-bit) dimming setting data DIMSETn on a relative or absolute basis. FIG. 10 is a diagram showing one example of the correspondence, in gradation dimming, between the range of the on-duty and the steps in which the on-duty is changed. As shown there, as the on-duty increases, the steps are increased. In gradation dimming, the on-duty is increased from the current value to the target value in specified steps. Representing the on-duty at a high resolution allows the use of small minimum steps. In gradation or other dimming like this, small steps permit dimming through the updating of dimming setting data in the relative mode. Where the on-duty needs to be changed greatly, the absolute mode can be used.

For example, in a case where dimming setting data corresponding to 24 channels is updated, in the absolute mode, data of 24 channels×12 bits=36 bytes need to be transmitted and, in the relative mode, only data of 24 channel×8 bits=24 bytes needs to be transmitted and this helps reduce communication traffic. At a high PWM frequency in particular, reducing communication traffic is effective.

Consider a case where, as shown in FIG. 1, the RX terminals 10A of a plurality of semiconductor devices 10 are all connected to the same RXD terminal 40A of the CAN transceiver 40 and those semiconductor devices 10 are LED driver ICs. In this case, if dimming setting data is updated in each of the plurality of semiconductor devices 10, the reception data RX needs to be transmitted to one after another of the plurality of semiconductor devices 10 by serial communication, and thus reducing the communication traffic per communication session is effective.

### <<Low Resolution Mode>>

Next, a description will be given of how dimming setting data is updated when the resolution mode is set to the low resolution mode (HAMODE=0). It is here assumed, as one example, that the second predetermined number of bits mentioned above is eight.

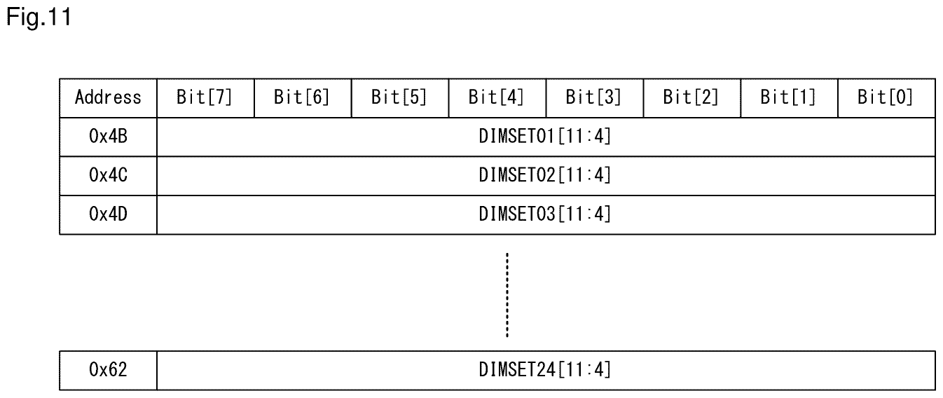

FIG. 11 is a diagram (register map) showing how dimming setting data DIMSETn is stored in the register 21 in the low resolution mode. FIG. 11 shows the correspondence between the addresses in the register 21 and the dimming setting data DIMSETn stored at those addresses.

At consecutive addresses from address 0x4B to address 0x62, DIMSET01 to DIMSET24, each eight-bit data, are stored respectively. Accordingly, in the low resolution mode, the register map is changed from that in the high resolution mode (FIG. 5).

In this case, with the reception data RX, transmission is performed in the following manner. In the register map (FIG. 11) of the register 21, the address corresponding to the beginning channel for which the dimming setting data needs to be updated is specified in the address frame Address. Moreover, the dimming setting data DIMSETn corresponding to consecutive addresses starting with the address specified in the above register map corresponding to as many channels as needed is transmitted in the data frame DataN.

For example, when data corresponding to 24 channels is transmitted, 0x4B is specified in the address frame Address and DIMSET01 to DIMSET24 are transmitted in the data frames Data1 to Data24.

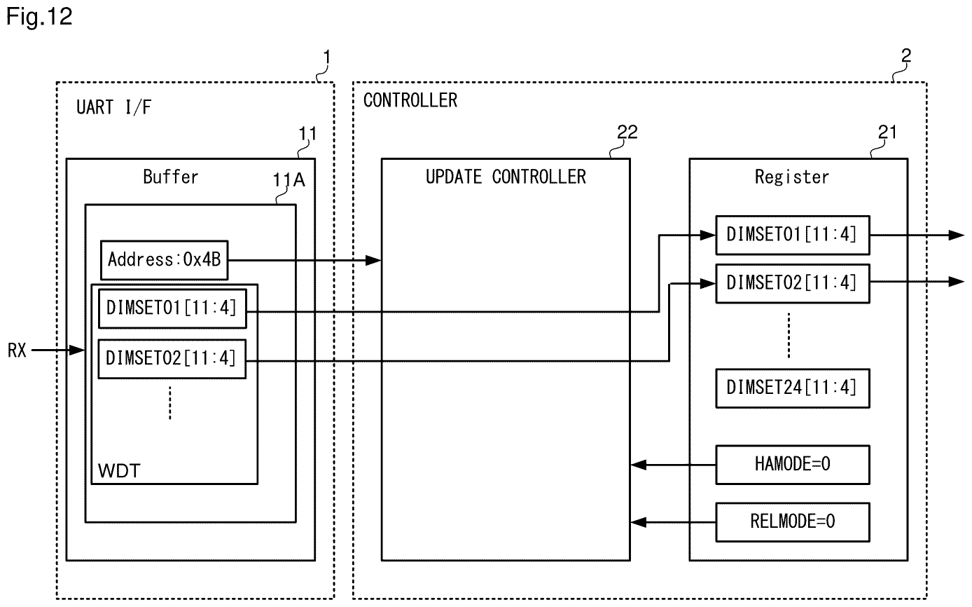

FIG. 12 is a configuration diagram showing an example of updating the dimming setting data DIMSETn when the low resolution mode is set and in addition the absolute mode is set (HAMODE=0, RELMODE=0; corresponding to FIG. 4).

In the example in FIG. 12, reception data RX is input to the UART interface 1 and reception data 11A is stored in a buffer 11. The reception data 11A includes, along with the address 0x4B, write data WDT. The write data WDT includes DIMSET01, DIMSET 02, and the like. Thus, based on the address 0x4B and DIMSET01, DIMSET02, and the like, the update controller 22 updates DIMSET01, DIMSET02, and the like in the register 21.

In the low resolution mode, owing to a register map as shown in FIG. 11, by specifying an address with the address frame Address, it is possible to update the dimming setting data DIMSETn with addresses incremented from the specified address. That is, the updating of dimming setting data DIMSETn for a plurality of channels can be achieved through a single session of transmission of reception data RX, and this helps reduce communication traffic.

In the low resolution mode, even absolute updating proceeds with reduced communication traffic and thus the relative mode is not used.

### <5. Group Setting Function>

The semiconductor device 10 can have a group setting function as described below.

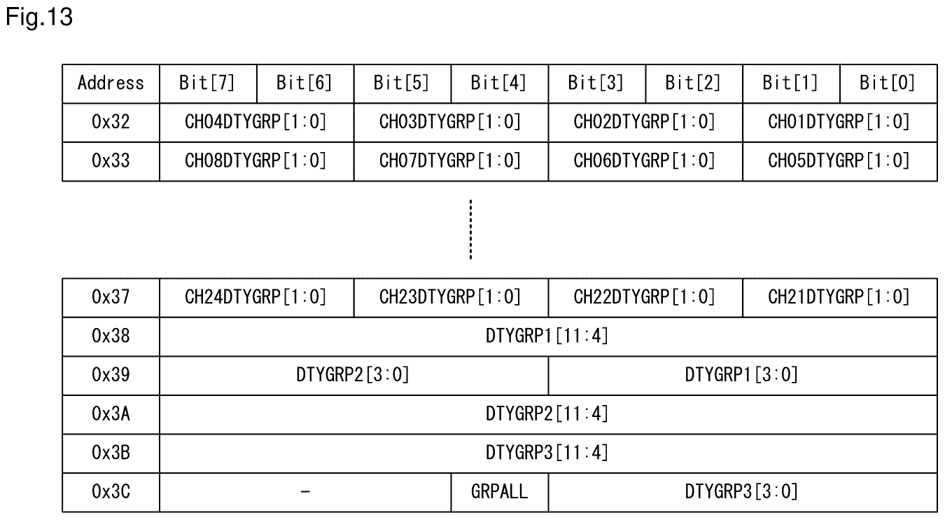

FIG. 13 is a diagram showing the register map in the register 21 related to the group setting function. In the example in FIG. 13, group setting data GHnDTYGRP is stored at each of consecutive addresses 0x32 to 0x37. The group setting data GHnDTYGRP is two-bit data and indicates the group setting for channel CHn. For example, CHnDTYGRP=01 indicates setting to a first group, CHnDTYGRP=10 indicates setting to a second group, and CHnDTYGRP=11 indicates setting to a third group.

Specifically, in FIG. 13, at address 0x32, CH04DTYGRP to CHOIDTYGRP are stored in order from the highest bit; at address 0x33, CH08DTYGRP to CH05DTYGRP are stored in order from the highest bit; and so forth up to CH24DTYGRP.

In FIG. 13, at each of consecutive addresses from 0x38 to 0x3C, duty setting value data DTYGRPm is stored. The duty setting value data DTYGRPm is 12-bit data and indicates the on-duty value set for the mth group.

Specifically, in FIG. 13, at address 0x38, the upper eight bits of DTYGRP1 are stored; at address 0x39, the lower four bits of DTYGRP2 and the lower four bits of DTYGRP1 are stored; at address 0x3A, the upper eight bits of DTYGRP2 are stored; at address 0x3B, the upper eight bits of DTYGRP3 are stored; and at address 0x3C, the lower four bits of DTYGRP3 are stored. Moreover, at address 0x3C, all channel updating mode setting data GRPALL (one bit) is stored.

In the reception data RX, address 0x32 is specified in the address frame Address and, in addition to the group setting data CH01DTYGRP to CH24DTYGRP, the duty setting value data DTYGRPm corresponding to the needed number of groups are transmitted in the data frame DataN.

Based on the data transmitted in the reception data RX as described above, the group setting data CH01DTYGRP to CH24DTYGRP and the duty setting value data DTYGRPm in the register 21 are updated. Then, the dimming setting data DIMSETn for channel CHn grouped.according to the group setting data CH01DTYGRP to CH24DTYGRP is updated based on the duty setting value data DTYGRPm corresponding to the groups.

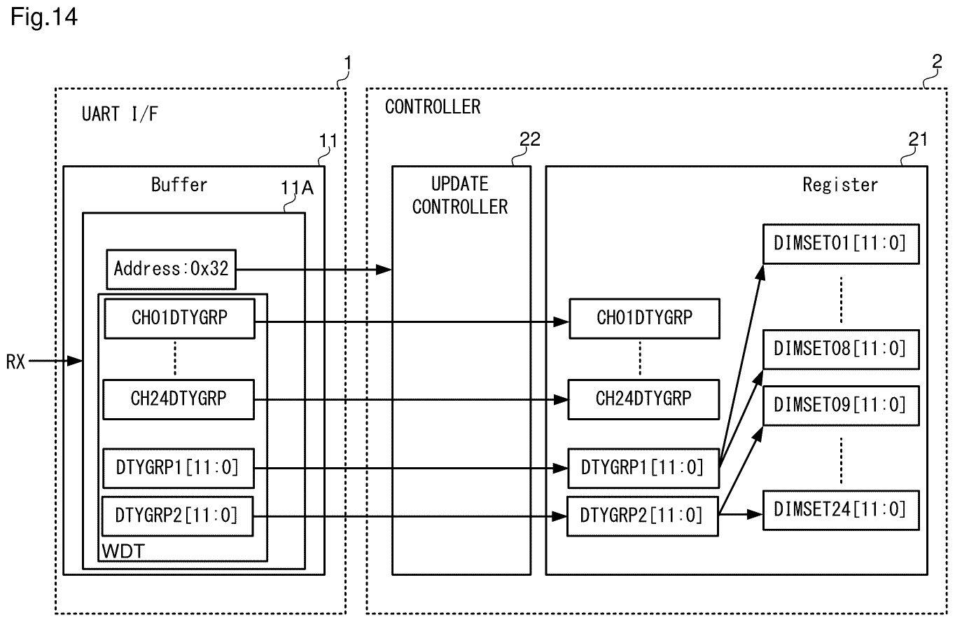

FIG. 14 is a configuration diagram (corresponding FIG. 4) showing an example of updating the dimming setting data DIMSETn using the group setting function. In the example in FIG. 14, reception data RX is input to the UART interface 1 and reception data 11A is stored in a buffer 11. The reception data 11A includes, along with address 0x32, write data WDT. The write data WDT includes group setting data CH01DTYGRP to CH24DTYGRP and duty setting value data DTYGRP1 and DTYGRP2. That is, in the example in FIG. 14, the number of groups for grouping is two.

The update controller 22 updates, based on the group setting data CH01DTYGRP to CH24DTYGRP, the group setting data CH01DTYGRP to CH24DTYGRP in the register 21 and, based on the duty setting value data DTYGRP1 and DTYGRP2, the duty setting value data DTYGRP1 and DTYGRP 2 in the register 12.

For example, in a case where, according to the group setting data CH01DTYGRP to CH24DTYGRP, channels CH01 to 08 are set to a first group and channels CH09 to 24 are set to a second group, then as shown in FIG. 14, in the register 21, the dimming setting data DIMSET01 to 08 is updated with the duty setting value data DTYGRP1 and the dimming setting data DIMSET09 to 24 is updated with the duty setting value data DTYGRP2. The updating of the dimming setting data is performed by the update controller 22.

With this group setting function, in a case like the example in FIG. 14, the updating of dimming setting data corresponding 24 channels requires, in addition to six bytes (=two bits×24 channels) through the transmission of group setting data CH01DTYGRP to CH24DTYGRP, three bytes through the transmission of duty setting value data DTYGRP1 and DTYGRP2 corresponding to two groups, and thus requires the transmission of a total of nine bytes. By contrast, in a case where as described above the high resolution mode is set and in addition the absolute mode is set, the transmission of 12 bits×24 channels=36 bytes is needed. Thus, the group setting function helps reduce communication traffic.

Incidentally, if the all channel updating mode setting data GRPALL is, for example, zero, the group setting function is enabled and the all channel updating mode is disabled. On the other hand, if GRALL is, for example, one, the group setting function is disabled and the all channel updating mode is enabled. In this case, the dimming setting data DIMSETn corresponding to all the channels (24 channels) is updated to be the same value based on, for example, DTYGRP3.

### <6. Notes>

The various technical features disclosed herein may be implemented in any manners other than as in the embodiments described above, and allow for many modifications without departure from the spirit of their technical ingenuity. That is, the embodiments described above should be understood to be in every aspect illustrative and not restrictive, and the technical scope of the present disclosure is not limited by the embodiments described above but encompasses any modifications within a scope equivalent in significance to what is claimed.

For example, serial communication is not limited to UART communication and can be I²C communication or the like.

### <7. Overview>

As described above, according to one aspect of the present disclosure, a semiconductor device (10) includes:
an interface (1) configured to receive, from outside, write data (WDT) transmitted by serial communication;
a updating controller (22) having a relative calculator (221) configured to perform calculation based on the write data; and
a register (21) configured to store duty setting data (DIMSETn) indicating a duty value for pulse-width modulation,
wherein
the write data incudes:
   a sign data (CHnSG) indicating decrementing or incrementing;
   a gain data (CHnGAIN) indicating a gain value; and
   a relative value data (DUTYn) indicating a relative change value,
the relative calculator calculates a calculation result by decrementing or incrementing, according to the sign data, the current value of the duty setting data by the value obtained by multiplying the relative change value by the gain value, and
the updating controller updates the duty setting data according to the calculation result. (A first configuration.)

With this configuration, it is possible to update the duty value for PWM on a relative basis and to reduce the volume of write data. It is thus possible to achieve the challenge of reducing communication traffic in serial communication during setting for PWM control.

The first configuration described above can be modified such that the gain value can be set to one according to the gain data. (A second configuration.)

The first or second configuration described above can be modified such that the total number of bits (e.g., eight bits) which is the sum of the number of bits of the sign data, the number of bits of the gain data, and the number of bits of the relative value data is less than a first predetermined number of bits (e.g., 12 bits) of the duty setting data. (A third configuration.)

The third configuration described above can be modified such that the semiconductor device has: a relative mode in which the updating controller updates the duty setting data according to the calculation result; and an absolute mode in which the updating controller updates the duty setting data stored in the register according to the duty setting data having the first predetermined number of bits included in the write data transmitted by the serial communication. (A fourth configuration.)

The third or fourth configuration described above can be modified such that the semiconductor device has: a high resolution mode in which the duty setting data stored in the register has the first predetermined number of bits (e.g., 12 bits); and a low resolution mode in which the duty setting data stored in the register has a second predetermined number of bits (e.g., eight bits) less than the first predetermined number of bits. (A fifth configuration.)

The fifth configuration described above can be modified such that, in the register, the number of bits of data that can be stored at one address is the second predetermined number of bits; that, in the high resolution mode, in the register, the upper bits of the duty setting data for a first channel are stored at a first address (e.g., 0x4B), the lower bits of the duty setting data for the first channel and the lower bits of the duty setting data for a second channel are stored at a second address (e.g., 0x4C) incremented from the first address, and the upper bits of the duty setting data for the second channel are stored at a third address (e.g., 0x4D) incremented from the second address; and that, in the low resolution mode, in the register, the duty setting data for each channel is stored at the corresponding one of consecutive addresses. (A sixth configuration; FIGS. 5 and 11.)

Any of the first to sixth configurations described above can be modified such that the register stores the duty setting data for a plurality of channels, and that the sign data, the gain data, and the relative value data correspond to the plurality of channels. (A seventh configuration.)

Any of the first to seventh configurations described above can be modified such that the semiconductor device can perform PWM dimming based on the duty setting data. (An eighth configuration.)

The eighth configuration described above can be modified such that the semiconductor device can perform gradation dimming in which the on-duty of the PWM dimming is increased in steps such that, as the on-duty increases, the steps in which the on-duty is changed increase. (A ninth configuration.)

Any of the first to ninth configurations described above can be modified such that the register stores the duty setting data for a plurality of channels, and that, if the write data includes group setting data (CHnDTYGRP) for setting a group for each of the plurality of channels and duty setting value data (DTYGRPm) for setting the duty value for each group, the updating controller updates the duty setting data based on the group setting data and the duty setting value data. (A tenth configuration.)

The tenth configuration described above can be modified such that the semiconductor device has: a mode in which the duty setting data is updated based on the group setting data and the duty setting value data; and a mode in which the duty setting data corresponding to all of the plurality of channels is updated based on the duty setting value data corresponding to a predetermined one of the groups. (An eleventh configuration.)

Any of the first to eleventh configurations described above can be modified such that the serial communication is UART communication. (A twelfth configuration.)

According to another aspect of the present disclosure, a communication system (501) includes: the semiconductor device (10) of any of the first to twelfth configurations described above; and a transmission device (40) configured to transmit the write data. (A thirteenth configuration.)

The thirteenth configuration described above can be modified such that the input terminals (10A) that are provided one for each of a plurality of semiconductor devices and that are configured to have the write data input to them are all connected to a single output terminal (40A) provided in the transmission device. (A fourteenth configuration.)

### INDUSTRIAL APPLICABILITY

The present disclosure finds applications in, for example, communication systems for use on-board vehicles.

### REFERENCE SIGNS LIST

1 UART interface
2 controller
3 PWM generator
4 current driver
6 LED
10 semiconductor device
10A RX terminal
10B TX terminal
10C cathode terminal
11 buffer
11A reception data
21 register
22 update controller
30, 40 can transceiver
30A TXD terminal
30B RXD terminal
35 CAN bus
40A RXD terminal
40B TXD terminal
221 relative calculator
501 communication system

1. A semiconductor device comprising:
an interface configured to receive, from outside, write data transmitted by serial communication;
a updating controller having a relative calculator configured to perform calculation based on the write data; and
a register configured to store duty setting data indicating a duty value for pulse-width modulation,
wherein
the write data incudes:
a sign data indicating decrementing or incrementing;
a gain data indicating a gain value; and
a relative value data indicating a relative change value,
the relative calculator calculates a calculation result by decrementing or incrementing, according to the sign data, a current value of the duty setting data by a value obtained by multiplying the relative change value by the gain value, and
the updating controller updates the duty setting data according to the calculation result.

2. The semiconductor device according to claim 1, wherein
the gain value can be set to one according to the gain data.

3. The semiconductor device according to claim 1, wherein
a total number of bits which is a sum of a number of bits of the sign data, a number of bits of the gain data, and a number of bits of the relative value data is less than a first predetermined number of bits of the duty setting data.

4. The semiconductor device according to claim 3, wherein
the semiconductor device has:
a relative mode in which the updating controller updates the duty setting data according to the calculation result; and
an absolute mode in which the updating controller updates the duty setting data stored in the register according to the duty setting data having the first predetermined number of bits included in the write data transmitted by the serial communication.

5. The semiconductor device according to claim 3, wherein
the semiconductor device has:
a high resolution mode in which the duty setting data stored in the register has the first predetermined number of bits; and
a low resolution mode in which the duty setting data stored in the register has a second predetermined number of bits less than the first predetermined number of bits.

6. The semiconductor device according to claim 5, wherein
in the register, a number of bits of data that can be stored at one address is the second predetermined number of bits,
in the high resolution mode, in the register,
upper bits of the duty setting data for a first channel are stored at a first address, lower bits of the duty setting data for the first channel and lower bits of the duty setting data for a second channel are stored at a second address incremented from the first address and
upper bits of the duty setting data for the second channel are stored at a third address incremented from the second address, and
in the low resolution mode, in the register,
the duty setting data for each channel is stored at a corresponding one of consecutive addresses.

7. The semiconductor device according to claim 1, wherein
the register stores the duty setting data for a plurality of channels, and
the sign data, the gain data, and the relative value data correspond to the plurality of channels.

8. The semiconductor device according to claim 1, wherein
the semiconductor device can perform PWM dimming based on the duty setting data.

9. The semiconductor device according to claim 8, wherein
the semiconductor device can perform gradation dimming in which an on-duty of the PWM dimming is increased in steps such that, as the on-duty increases, the steps in which the on-duty is changed increase.

10. The semiconductor device according to claim 1, wherein
the register stores the duty setting data for a plurality of channels, and
if the write data includes group setting data for setting a group for each of the plurality of channels and duty setting value data for setting the duty value for each group, the updating controller updates the duty setting data based on the group setting data and the duty setting value data.

11. The semiconductor device according to claim 10, wherein
the semiconductor device has:
a mode in which the duty setting data is updated based on the group setting data and the duty setting value data; and
a mode in which the duty setting data corresponding to all of the plurality of channels based on the duty setting value data corresponding to a predetermined one of the groups.

12. The semiconductor device according to claim 1, wherein
the serial communication is UART communication.

13. A communication system comprising:
the semiconductor device according to claim 1; and
a transmission device configured to transmit the write data.

14. The communication system according to claim 13, wherein
input terminals that are provided one for each of a plurality of the semiconductor devices and that are configured to have the write data input thereto are all connected to a single output terminal provided in the transmission device.
